(19) United States
(12) Patent Application Publication
(10) Pub. No.: US 2010/0044727 A1
(43) Pub. Date: Feb. 25, 2010

(54) LED PACKAGE STRUCTURE

(76) Inventor: Shih-Hao Hung, Kaohsiung County (TW)

Correspondence Address: NORTH AMERICA INTELLECTUAL PROPERTY CORPORATION, P.O. BOX 506, MERRIFIELD, VA, 22116, US

(21) Appl. No.: 12/489,439

(22) Filed: Jun. 23, 2009

(30) Foreign Application Priority Data
Aug. 21, 2008 (CN) 200810030373.8

(51) Int. Cl. H01L 27/15; H01L 33/00

(52) U.S. Cl. 257/88; 257/98; 257/99; 257/E27.121; 257/E33.066; 257/E33.058; 257/E33.068

(57) ABSTRACT

A LED package structure includes an insulating ceramic base, whereon a first surface and a second surface are formed. The LED package structure further includes a casing disposed on the first surface of the insulating ceramic base. A hole is formed on the casing. The LED package structure further includes a heat-dissipating structure connected to the second surface of the insulting ceramic base, at least one LED chip, and at least one conductive circuit disposed inside the casing. The conductive circuit includes a first conductive portion, and a second conductive portion connected to the first conductive portion via the hole and electrically connected to the LED chip.

### BACKGROUND OF THE INVENTION

1. Field of the Invention

The present invention relates to an LED package structure, and more particularly, to an LED package structure with enhanced heat-dissipating efficiency.

2. Description of the Prior Art

Recently, light emitting diode (LED) is applied widely in different fields, such as a light source in a liquid crystal display, a projecting light, a traffic light, a brake light on a vehicle, and so on, and replaces a traditional incandescent lamp gradually. Although the conventional LED has properties of small size and low energy dissipation, the single conventional LED has lower luminance than the traditional incandescent lamp so that its application is limited. In order to improve luminance of the LED, it is necessary to advance light-emitting efficiency of the LED and to increase amount and intensity of LED chips. But if the amount and the intensity of the LED are increased, the LED chips generate more heat accordingly.

Please refer to FIG. 1. FIG. 1 is a diagram of an LED package structure 1′ in the prior art. The LED package structure 1′ includes an insulating base 10′, a LED chip 20′, a conductive wire 40′, and two conductive circuits 50′. The LED chip 20′ connects to the two conductive circuits 50′ via the conductive wire 40′, respectively. The LED chip 20′ is fixed on a first surface 101′ of the insulating base 10′. An end of any conductive circuit 50′ is disposed on the first surface 101′ of the insulating base 10′, and the other end of the conductive circuit 50′ is disposed on a second surface 102′ of the insulating base 10′, so that the two conductive circuits 50′ dispose around lateral sides of the insulating base 10′. The conductive circuits 50′ are made of metal material with advanced heat dissipating efficiency. Besides conductibility, the conductive circuits 50′ have a function of dissipating heat generated by the LED chip 20′. Because electrode polarities of the two conductive circuits 50′ are reverse, the two conductive circuits 50′ can not be disposed closely for preventing other electrical components from leaking electricity and for preventing short circuit between the two conductive wires 50′. There is a gap formed between the two conductive circuits 50′, so that the heat-dissipating area thereon is decreased. The light-emitting efficiency is influenced upon the heat-dissipating efficiency, and if the heat can not be dissipated as soon as possible, the light-emitting efficiency and the service life of the LED chip are reduced.

### SUMMARY OF THE INVENTION

It is therefore a primary objective of the claimed invention to provide an LED package structure with enhanced heat-dissipating efficiency.

The LED package structure of the present invention utilizes the ceramic insulating base to improve heat-dissipating efficiency of the LED chip, and disposes the conductive circuit through the casing instead of disposing the conductive circuit around the ceramic insulating base for preventing short circuit, poor heat dissipation, and poor contact. Furthermore, the heat-dissipating efficiency can be improved by connecting the insulating ceramic base to the heat-dissipating structure directly, and the heat-dissipating structure can be installed on surfaces of the insulating ceramic base without regarding limitation of electrode polarities so as to increase heat-dissipating area. Therefore, the heat-dissipating efficiency and the light-emitting efficiency of the LED chip can be improved.

Furthermore, the LED package structure includes a plurality of LED chips electrically connected to each other in series or in parallel by a plurality of conductive circuits to install a multi-chip package structure for simplifying the package structure and improving light-emitting efficiency.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of an LED package structure in the prior art.

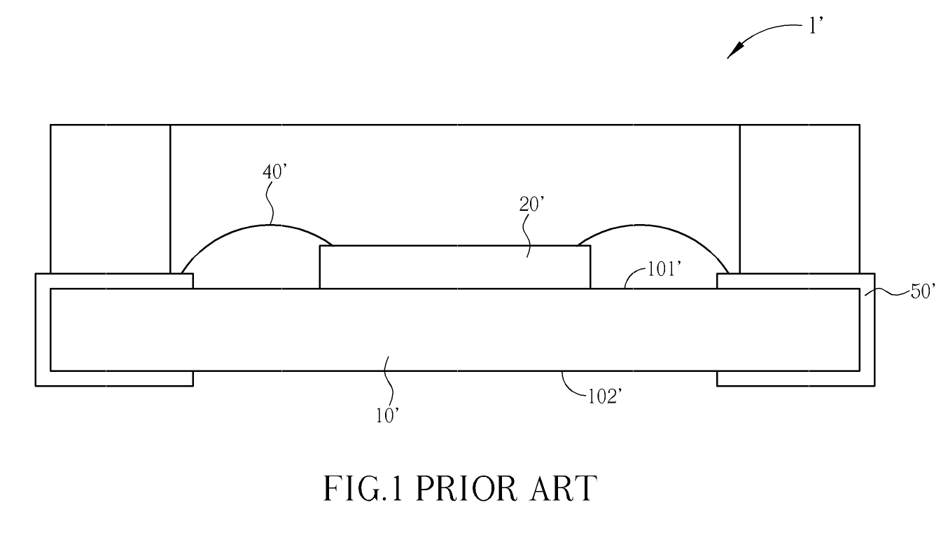

FIG. 2 is a diagram of an LED package structure according to a first embodiment of the present invention.

FIG. 3 is a diagram of the LED package structure according to a second embodiment of the present invention.

FIG. 4 is a diagram of a plurality of LED chips electrically connected to one another in series of the present invention.

FIG. 5 is a diagram of a plurality of LED chips electrically connected to one another in parallel of the present invention.

### DETAILED DESCRIPTION

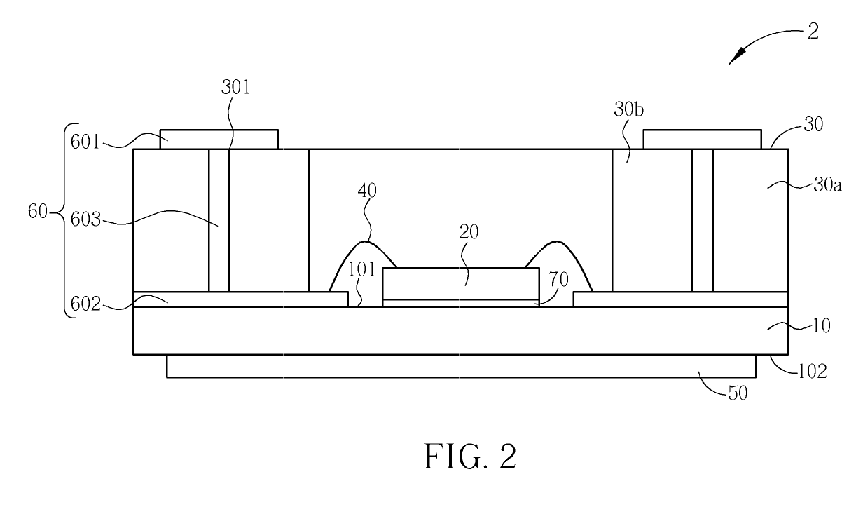

Please refer to FIG. 2. FIG. 2 is a diagram of an LED package structure 2 according to a first embodiment of the present invention. The LED package structure 2 includes an insulating ceramic base 10, a LED chip 20, a casing 30, a conductive wire 40, a heat-dissipating structure 50, and two conductive circuits 60. A first surface 101 and a second surface 102 are formed on the insulating ceramic base 10. The casing 30 is disposed on the first surface 101 of the insulating ceramic base 10, wherein a hole 301 is formed on the casing 30. The LED chip 20 is arranged on the first surface 101 of the insulating ceramic base 10. The conductive circuits 60 disposed inside the casing 30 includes a first conductive portion 601 and a second conductive portion 602 connected to the first conductive portion 601 via the hole 301. The LED chip 20 is electrically connected to the second portion 602. The heat-dissipating structure 50 is arranged on the second surface 102 of the insulting ceramic base 10. Because the heat-dissipating structure 50 and the insulating ceramic base 10 are connected closely, heat generated by the LED chip 20 can be dissipated by the heat-dissipating structure 50 rapidly so as to improve heat-dissipating efficiency and light-emitting efficiency.

A thermal conductivity of the insulating ceramic base 10 is between 30 W/mK and 420 W/mK substantially, or between 50 W/mK and 420 W/mK preferably. For example, the insulating ceramic base 10 can be made of aluminum nitride (AlN), which has a thermal conductivity as 170 W/mK. In this embodiment, the casing 30 is located around the insulating ceramic base 10 for combining with the two conductive circuits 60 having reverse electrode polarities. The casing 30 includes two package units 30a and 30b erecting on two sides of the conductive circuits 60 respectively, which can be integrated monolithically or be disposed separately. The conductive circuits 60 can be made of metal, such as silver and copper. The conductive circuits 60 includes the first conductive portion 601, the second conductive portion 602 connected to the first conductive portion 601, and a conductive stick 603. The first conductive portion 601 is disposed on an outer surface of the casing 30 for electrically connecting to an external power. The second conductive portion 602 is disposed on the first surface 101 of the insulating ceramic base 10, where is between the insulating ceramic base 10 and the casing 30. The conductive stick 603 is accommodated inside the hole 301. The conductive circuits 60 connect to the LED chip 20 electrically via the conductive wire 40 so that the LED chip 20 can connect to the external power electrically. The conductive wire 40 disposed on the first surface 101 of the insulating ceramic base 10 can be made of material having enhanced conductivity, such as gold.

In this embodiment, a shape of the hole 301 is not limited. The hole 301 is formed to pass through the casing 30 so that the first conductive portion 601 of the conductive circuits 60 can connect to the second conductive portion 602 electrically via the hole 301. Thus, the LED chip 20 is simplified without disposing the conductive circuits 60 on the casing 30 outside for connecting to the external power, so that conventional problems of short circuit and poor contact due to exposure of the conductive circuits can be solved. Conductivity of the conductive circuits 60 is enhanced for improving the heat-dissipating efficiency of the LED chip 20 by packaging and isolating the conductive circuits 60.

In this embodiment, as shown in FIG. 2, the LED package structure 2 further includes a connecting layer 70 disposed between the LED chip 20 and the insulating ceramic base 10. The LED chip 20 can be installed on the insulating ceramic base 10 in chip on board (COB) technology, flip-chip technology, tackifier method, or eutectic welding technology selectively.

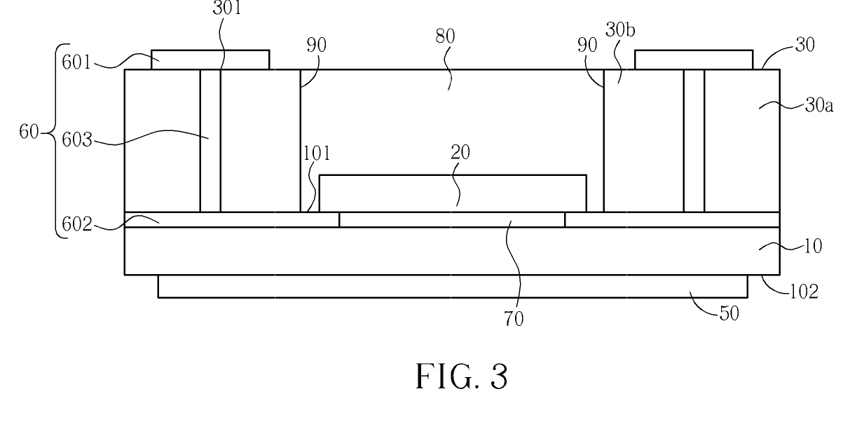

Please refer to FIG. 3. FIG. 3 is a diagram of the LED package structure 2 according to a second embodiment of the present invention. In this embodiment, the conductive wire 40 is omitted so that the LED chip 20 can be fixed on the insulating ceramic base 10 in flip-chip technology for electrically connecting to the conductive circuits 60 directly. The connecting layer 70 of the second embodiment is a conductive layer. A terminal (without showing in FIG. 3) is further disposed between the second portion 602 of the conductive circuits 60 and the LED chip 20 for fixing the LED chip 20, and is utilized to electrically connect p/n electrode polarities of the LED chip 20 and the second portions 602 with reverse electrode polarities. The terminal can be made of tin adhesive or soldering tin.

In this embodiment, the LED chip 20 is disposed in a closed space 80, which is formed by the package unit 30b of the casing 30 and the insulating ceramic base 10. The closed space 80 can be filled with gum. A reflective region 90 is formed on inner surfaces of the package unit 30b and the insulating ceramic base 10. The reflective region 90 can be plated with material having high reflectivity, such as ceramic, paint, or reflective metal. A reflectivity of the reflective region 90 can be between 85% and 100% substantially. The package unit 30b can be made of the material having high reflectivity too.

The heat-dissipating structure 50 can be a thermal module or a metal conductive layer. If the heat-dissipating structure 50 is the metal conductive layer, the metal conductive layer can cover the second surface 102 of the insulating ceramic base 10 by reflow soldering method and be made of metal selected from the group consisting of silver, copper, aluminum, and alloy thereof. The second surface 102 of the insulating ceramic base 10 can be covered by the metal conductive layer entirely so as to increase heat-dissipating area, and the heat-dissipating efficiency and the light-emitting efficiency of the LED chip 20 can be improved accordingly. At the same time, the LED package structure 2 and the surface mounting process can be simplified.

The LED package structure 2 can includes a single conductive circuit or a plurality of conductive circuits 60, and the structure of each conductive circuit 60 is not limited to the above-mentioned structure of the conductive circuit 60. The LED package structure 2 of the present invention includes two conductive circuits 60 preferably. The two conductive circuits 60 with reverse electrode polarities pass through the casing 30 respectively so as to connect with the LED chip 20 and the external power electrically.

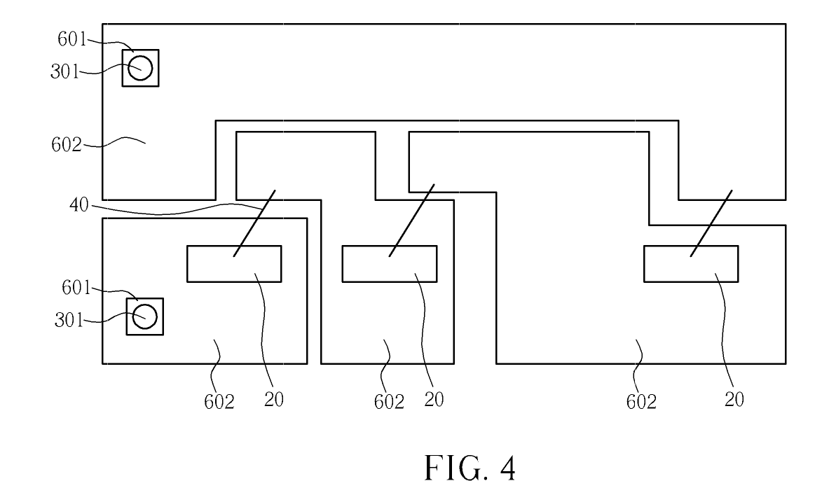

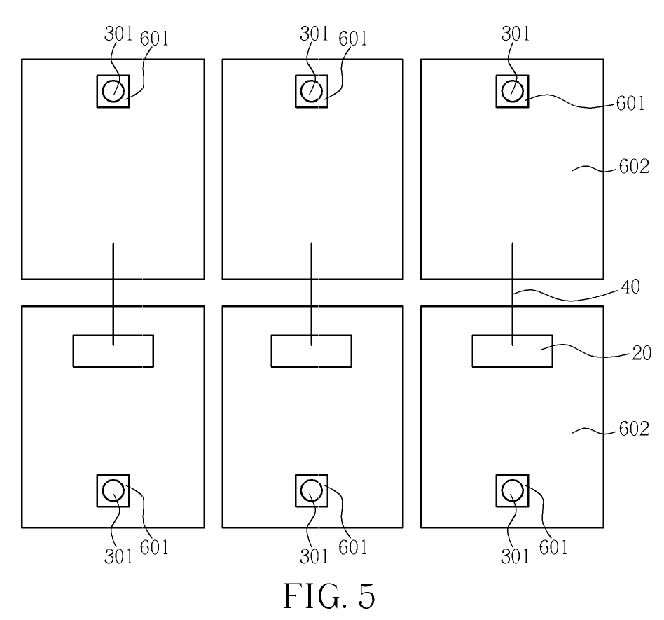

Please refer to FIG. 4 and FIG. 5. FIG. 4 is a diagram of a plurality of LED chips 20 electrically connected to one another in series of the present invention. As shown in FIG. 4, the plurality of the LED chips 20 is respectively disposed on a plurality of casings (without showing in FIG. 4) and electrically connected to one another in series via a plurality of conductive wires 40, and connect with the external power by the two first conductive portions 601. FIG. 5 is a diagram of a plurality of LED chips 20 electrically connected to one another in parallel of the present invention. As shown in FIG. 5, the plurality of the LED chips 20 is respectively disposed on a plurality of casings (without showing in FIG. 5) and has a plurality of conductive circuits 60 individually, so that the plurality of the LED chips 20 utilizes a plurality of first conductive portions 601 to connect with the external power. The plurality of the conductive circuits 60 in parallel and the plurality of the LED chips 20 in parallel can be formed in this embodiment.

In conclusion, the structure and the type of the LED chip are not limited. That is, the types and the structures of the LED chips can be different. Similarly, the structure and the type of the conductive circuit are not limited. That is, the types and the structures of the conductive circuits of the LED chips can be different. The present invention minimizes the whole volume of the LED package structure and improves the light-emitting efficiency per area and light-emitting intensity. The connection of the LED chips is not limited and depends on assembly of the conductive circuit and the LED chip.

Those skilled in the art will readily observe that numerous modifications and alterations of the device and method may be made while retaining the teachings of the invention.

What is claimed is:

1. A LED package structure comprising:
an insulating ceramic base having a first surface and a second surface;
a casing disposed on the first surface of the insulating ceramic base, wherein a hole is formed on the casing;
a heat-dissipating structure arranged on the second surface of the insulting ceramic base;
at least one LED chip arranged on the first surface of the insulting ceramic base; and
at least one conductive circuit disposed inside the casing, wherein the conductive circuit comprises a first conductive portion and a second conductive portion connected to the first conductive portion via the hole and electrically connected to the LED chip.

2. The LED package structure of claim 1 further comprising:
a conductive wire for electrically connecting with the LED chip and the conductive circuit.

3. The LED package structure of claim 1 further comprising:
a connecting layer for fixing the LED chip on the insulating ceramic base.

4. The LED package structure of claim 1, wherein the LED package structure comprises two conductive circuits, and electrode polarities of the two conductive circuits are reverse.

5. The LED package structure of claim 1, wherein the LED chip is installed on the insulating ceramic base in chip on board (COB) technology, flip-chip technology, tackifier method, or eutectic welding technology.

6. The LED package structure of claim 1, wherein a thermal conductivity of the insulating ceramic base is between 30 W/mK and 420 W/mK substantially.

7. The LED package structure of claim 1, wherein the heat-dissipating structure is a thermal module or a metal conductive layer.

8. The LED package structure of claim 7, wherein the metal conductive layer is formed on the insulating ceramic base by reflow soldering method, and the metal conductive layer is made of metal selected from the group consisting of silver, copper, aluminum, and alloy thereof.

9. The LED package structure of claim 1, wherein a reflective region is formed on inner surfaces of the casing and the insulating ceramic base and a reflectivity of the reflective region is between 85% and 100% substantially.

10. The LED package structure of claim 1, wherein the LED package structure comprises a plurality of LED chips electrically connected in series or in parallel.
